(19) United States
(12) Patent Application Publication
(10) Pub. No.: US 2010/0129564 A1
(43) Pub. Date: May 27, 2010

(54) Method for deposition of electrochemically active thin films and layered coatings

(75) Inventors: Elena M. Shembel, Coral Springs, FL (US); Boris Tugay, Kiev (UA); Anatolii Demchyshyn, Kiev (UA); Volodymyr Redko, Coral Springs, FL (US); Tymofiy V. Pastushkin, Ft. Lauderdale, FL (US); Stanislav Denbnovetskyy, Kiev (UA); Vitalyy Melnyk, Kiev (UA); Igoz Melnyk, Kiev (UA); Alexandr Markevich, Dnipropetrovsk (UA)

Correspondence Address: Enerize Corporation;Elena Shembel, 4956 Rothschild Dr., Coral Springs, FL, 33067-4134, US

(73) Assignee: Enerize Corporation, Coral Springs, FL (US)

(21) Appl. No.: 12/148,758

(22) Filed: Apr. 22, 2008

Related U.S. Application Data
(60) Provisional application No. 60/926,704, filed on Apr. 28, 2007.

(51) Int. Cl. C23C 14/02; C23C 14/28

(52) U.S. Cl. 427/534; 427/566

(57) ABSTRACT

The present invention involves a method for deposition of thin film and electrochemically active layered coatings for use as components including electrodes and solid electrolytes for electrochemical generation and storage devices including batteries, supercapacitors, fuel cell, solar cell and the like. According to the present invention, evaporation of the starting materials in a reactive gaseous medium is accomplished by means of a gas discharge electron gun with a cold cathode. The electron beam has a given specific power corresponding to the evaporation temperature of the starting material. Deposition of the evaporated starting material onto the substrate in a pressure controlled reactive gaseous medium is carried out at a controlled temperature and rate of condensate formation. This temperature is dependant on the partial pressure of the reactive gas. High condensation rates can be achieved, and the resulting condensed coating materials can have high density, making them ideal for use as electrodes in electrochemical generation and storage devices.

### RELATED APPLICATIONS

This application claims priority to a provisional patent application Ser. No. 60/926,704, filed Apr. 28, 2007.

### FIELD OF THE INVENTION

The invention relates to methods of applying coatings in a vacuum or in a rarefied gaseous medium, and more particularly to electron beam methods of depositing coatings, especially condensed layers of electrochemically active materials, for use as electrodes in electrochemical energy generation and storage devices such as batteries, supercapacitors, photovoltaic cells, and the like.

### BACKGROUND OF INVENTION

Previously described methods for producing layered electrochemically active coatings of materials such as metal oxides in a vacuum or rarified gas atmosphere suffer from a number of drawbacks. For example, reactive ion implantation is a method wherein the oxide coatings are deposited using thermal electron beam evaporation of metals in a low pressure atmosphere containing oxygen, while activating the metal vapor and oxygen in a glow discharge that is maintained in the gap between the crucible and the substrate. In this method, the cathode surface can become coated with the material being evaporated from the crucible, adversely affecting the stability of the electron beam and, correspondingly, of the evaporation conditions.

These and similar untoward effects represent significant difficulties in the usage of such a method for producing adequate quality coatings, especially binary coatings that are sensitive to changes in deposition conditions (pressure and composition of the gas medium, evaporation temperature, condensation surface temperature, etc.).

### BRIEF DESCRIPTION OF THE INVENTION

According to the present invention, the general problem of maintaining quality of materials coatings while achieving an adequate material deposition rate is addressed by evaporation of the starting materials in a reactive gaseous medium by electron heating. Heating is accomplished by means of a gas discharge electron gun with a cold cathode.

According to the present invention, evaporation of the starting materials in the form of compacted blanks is effected by heating by means of a gas discharge electron gun during a pre-programmed scanning of the material surface. The electron beam has a given specific power corresponding to the evaporation temperature of the intended coating material (starting material). Physical deposition onto the substrate in a pressure controlled reactive gaseous medium is carried out at a controlled temperature to effect the desired condensate formation. This temperature is dependant on the partial pressure of the reactive gas.

Evaporation of the chemical compounds in vacuum is accompanied by a thermal dissociation and by partial degradation of the compounds during depletion of the more volatile component (oxygen in case of oxides).

Evaporation of such compounds according to the present invention is carried out by means of a scanning (according to the preset program) beam, specific power of which is maintained in correspondence of the material evaporation temperature that maintains the optimum temperature on the surface of the material being evaporated, while holding the dissociation of the compound to a minimum.

The coating is deposited in an atmosphere of activated gas (for example oxygen) at a pressure that provides compensation for the gas deficiency in the condensate composition. The formation of the coating structure and composition depends on the material condensation rate, substrate temperature, and reactive gas concentration within the coating chamber volume.

For a given coating deposition rate, the substrate temperature is maintained at a specific value depending on the partial pressure of the reactive gas in the chamber. The temperature is decreased with increase in pressure and vice versa. A given gas pressure in the vacuum chamber (or working chamber) is maintained by automatic regulation of the evacuation rate or by bleeding the reactive gas into the chamber continuously during evacuation. This provides the necessary conditions for producing condensed layers of a given stoichiometric composition from chemically active compounds.

### DESCRIPTION OF THE DRAWINGS

FIG. 1 shows a diagrammatic view of the apparatus for practicing the method of the present invention for deposition of thin films or layered coatings of electrochemically active compounds. It includes a vacuum chamber 101 with a cooled copper crucible 102, a gas discharge electron gun 103, a high voltage gun power supply source 104, gas bleed valves 105, 112, electron beam scanning coil 106, source for controlling the negative potential of the substrate 107, adjustable power source for the radiation heater 108, radiation heater 109, substrate 110, substrate temperature meter 111, electromagnetic deflection device 113.

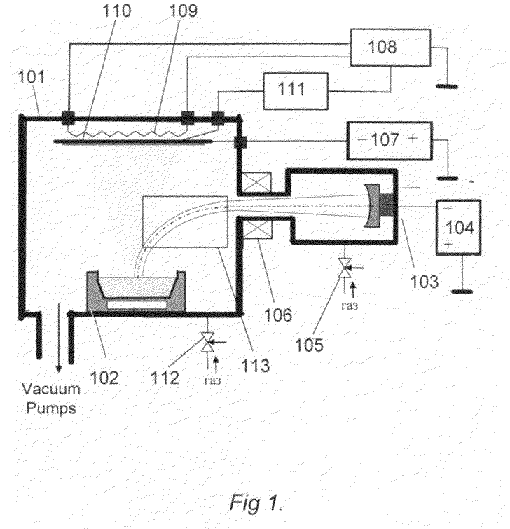

### DETAILED DESCRIPTION OF THE INVENTION

The method for producing condensed layers from chemically active compounds is implemented as follows. The vacuum chamber 101 with the gas discharge gun 103 is pumped out to 10⁻¹-10⁻² Pa by means of vacuum pumps. The gun cathode is biased with high voltage from a high voltage supply source 104 while gas bleed-in is performed via bleed valve 105. As the gas pressure in the gun reaches a value of several Pa, a high voltage glow discharge is ignited.

The electron beam thus formed in the gun is directed by onto the surface of the material placed in the cooled crucible 102 in the form of compacted blanks. The power of the electron beam is automatically controlled by varying the pressure in the gun while the specific power on the evaporation surface is regulated by means of a coil 106.

The beam deflection and scanning thereof on the surface of the material (compacted blank) according to a given program, is carried out by means of a electromagnetic deflection device 113. The temperature of the substrate 110 is maintained within a given range by means of a radiation heater 109, with this temperature being regulated as a function of the reactive gas pressure in the deposition zone. A negative potential of several kV is applied to the substrate by a source for controlling the negative potential of the substrate 107 during the coating deposition process.

The method of depositing coatings in an active gaseous medium according to the present invention is mainly intended for producing layers of binary compounds prone to thermal dissociation that are used as electrode or electrolyte materials for chemical power sources. It can be also used for producing coatings of stoichiometric composition from other compounds whose deposition presents difficulties when conventional methods are employed.

When implementing the method of this invention for producing condensed layers of various electrochemically active materials including electro-chemically active electrode materials and electrolytes, the following results are achieved: a high condensation rate of the thin layer of materials during electron beam evaporation while feeding reactive gas into the working chamber; production of coatings with a gradient of chemical composition; production of coating with a gradient of material density production of functional coatings comprised of 100% electrochemically active material without introduction of electrically conductive and binding additives (this advantageous feature is due to the presence of the metallic phase in the condensates and to the formation of layers at optimum temperatures of the substrate); upgraded specific electrochemical characteristics of the power sources due to the high specific weight of the condensed electrode active materials.

The electrochemical characteristics of the resulting thin films and coatings were studied after forming into electrodes for chemical power sources. The obtained results have demonstrated that the electrode samples feature high specific electrochemical capacity that allows their use in the development of state-of-the-art electrochemical power sources.

Studies of the process of depositing binary and mono coatings have shown that the methods of the present invention allows production of adequate quality condensed layers including electrochemically active electrode materials and electrolyte whose deposition by means of conventional methods is either very complicated or impossible. High condensation rates can be achieved, and the resulting condensed coating materials can have high density, making them ideal for use as electrodes in electrochemical generation and storage devices,

### EXAMPLE 1

A series of processes according to the present invention for depositing coatings from binary MnO₂ and MoO₃ compounds was carried out on a modernized experimental installation URMZ. Powders of the above materials were compacted to blanks of appropriate dimensions. The blanks were placed in a cooled copper crucible. Evaporation was effected using a 1.5-2 kW electron beam that was scanned the surface of the blanks. Oxygen was used as a working (reactive) gas.

The substrate temperature was regulated automatically as required for the material being deposited, and as a function of the working gas pressure, and was thus maintained within the 200-230° C. range. The coatings deposition rate, depending on the beam power, rate reached several tens of urn/s. The partial pressure of oxygen in the chamber was maintained automatically at the level of 0.1 Pa. The coatings were deposited onto the 0.2 mm thick stainless steel substrates.

Studies have demonstrated that the method of the present invention allows formation of active layers of the film of materials at high rates of 1-3 μm/s within a wide range of thickness values (from 0.5 μm to 1.0 mm). Stoichiometry of the materials being deposited can be regulated, by feeding the reactive gas into the working chamber at a regulated pressure and temperature of the substrate. The density of the cathode material being deposited can be regulated by varying the deposition parameters, and can be of the order of 2.6-3.9 G/cm³.

### EXAMPLE 2

A stainless steel substrate with a diameter of 16 mm and 250 μm thickness is placed in a vacuum chamber. With the help of electron-beam evaporator, the compacted blanks, which are the pressed MoO₃. powder, are subjected to evaporation. The substrate temperature is 230° C. The current of the electron beam is 45 mA. The pressure in a chamber is 1.5×10⁻¹ Pa. The vapor this formed is deposited on a substrate. X-ray phase analysis has shown the presence of MoO₃ phase in a deposited film.

The electrode produced according to Example 2, is placed into the case of “coin cell” The cell contains a lithium negative electrode and liquid non-aqueous electrolyte. The cell is sealed and tested. The discharge capacity of cell is measured in the process of galvanostatic cycling. The cycling conditions are as follows: discharge current is 37 μA/cm², charge current; 25 μA/cm², final charge voltage was 3.1 V, final discharge voltage was 1.5 V. The results of the testing show that the specific discharge capacity per unit of the weight of cathode material was 295 mA·h/g at the first discharge. In the process of cycling, during 20 charge-discharge cycles, this value changed gradually from 295 down to 70 mAh/g.

### EXAMPLE 3

A square nickel foil substrate, 15 mm on a side and 2 μm in thickness was placed in a vacuum chamber. With the help of electron -beam evaporator, the compacted blanks, which were pressed MoO₃ powder, were subjected to evaporation. The substrate temperature was 210° C. The current of the electron beam was 120 mA. The pressure in a chamber was 1.5×10⁻¹ Pa. The vapor thus formed was deposited on a substrate as a film of 9-12 μm thickness. X-ray phase analysis has shown the presence of the layer of stoichiometric MoO₃ as a deposited film.

The electrode produced by the conditions of Example 3, was placed into the case of flat battery which contained a lithium negative electrode and liquid non-aqueous electrolyte. The power source was sealed and tested. The discharge capacity was determined during the process of galvanostatic cycling. Cycling conditions were as follows: discharge current was 100 μA/cm², charge current was 50 μA/cm², final charge voltage was 3.1 V, and final discharge voltage was 1.5 V. The results of the testing show that a specific discharge capacity per the cathode material weight unit was 227 mA·h/g for the first discharge. The specific discharge capacity of cathode material for the 5^{th} cycle was 57 mAh/g, and for the 20^{th} cyclr, it was 32 mAh/g.

### EXAMPLE 4

A nickel foil substrate 15 mm in a side and 2μm thickness was placed in a vacuum chamber. With the help of electron -beam evaporator, compacted blanks which is the pressed MoO_{3.} powder, is subjected to evaporation. The substrate temperature is 210° C. The current of electron beam is 120 mA. The pressure in a chamber is 1.3*10⁻¹ Pa. The formed vapor is deposited on a substrate as a film of 9-12 μm thickness. The X-ray phase analysis has shown availability of the phase stoichiometric MoO₃ in the deposited film.

The electrode produced according to Example 4, was placed into a flat battery case that contained lithium negative electrode and liquid nonaqueous electrolyte. The resulting battery was sealed and tested. The discharge capacity was measured during the process of galvanostatic cycling. The test condition for this battery were of the model are similar to those of described in Example 3 above. The results of the testing show that the specific discharge capacity per unity of cathode material weight for the first discharge was 320 mAh/g. The specific discharge capacity of the cathode substance for the 5^{th} cycle was 216 mAh/g, at for the 20^{th} cycle it was 138 mAh/g.

### EXAMPLE 5

A stainless steel substrate 16 mm in diameter, and 250 μm thickness was placed in a vacuum chamber. With the help of electron -beam evaporator, the compacted blanks comprising pressed MoO₃ powder were subjected to evaporation. The substrate temperature was 200° C. The current of the electron beam was 30 mA. The pressure in the chamber was 1.10⁻¹ Pa. The vapor thus formed was deposited on a substrate as the film of 4-6 μm thickness. X-ray phase analysis showed the presence of stoichiometric MoO₃ in the deposited film

The electrode produced according to Example 5 was placed into a coin cell battery case that contained lithium negative electrode and liquid nonaqueous electrolyte. The battery was sealed and tested. The discharge capacity is measured by the process of galvanostatic cycling. The conditions of the electrochemical tests were similar to the conditions of Example 2. The results of the testing show that the specific discharge capacity per unit weight of the cathode material was 305 mAh/g. In the cycling process during 20 charge-discharge cycles, this value changed gradually from 305 [symbol] o 160 mA*h/g.

While various embodiments of the present invention have been shown and described, it will be apparent to those skilled in the art that many changes and modifications may be made without departing from the invention in its broader aspects. The appended claims are therefore intended to cover all such changes and modifications as fall within the true spirit and scope of the invention.

We claim:

1. A method for producing thin film or layered coatings, wherein evaporation of an initial (starting) material that will comprise the deposited materials, in the form of compacted blanks, is effected by heating with a gas discharge electron gun with a cold cathode in a reactive gaseous medium while said starting material surface is scanned with a the resulting electron beam having a given specific power relative to the evaporation temperature of said starting materials, thus providing a given power distribution over the blank surface of said starting material, and wherein the resulting vapor stream of said starting material is subsequently deposited onto the substrate in a reactive pressure-controlled gaseous medium that is activated in the high-voltage glow discharge of the electron gun at a controlled temperature at which the condensate forms, said temperature being dependant on the partial pressure of the reactive gas.

2. A method for producing thin film materials as in claim 1, wherein the said thin film or coating is deposited under an atmosphere of the activated gas at the given pressure that provides compensation for the gas shortfall in the condensate composition.

3. A method for producing thin film materials as in claim 2, wherein the active gas is comprised of oxygen, compositions of sulphide or nitrogen.

4. A method for producing thin film materials as in claim 2, wherein the active gas partial pressure in the chamber for material deposition onto the substrate is automatically maintained at the 1.10⁻¹-5.10⁻² Pa by automatic adjustment of the pump-down rate by bleed-in of the reactive gas into the chamber, which is continuously pumped and is directly fed into the material evaporation/deposition zone and into the glow discharge area.

5. A method for producing thin film materials as in claim 1, wherein the vacuum chamber with the gas discharge gun are pumped down by means of vacuum pumps to 10⁻¹-10⁻³ Pa.

6. A method for producing thin film materials as in claim 1, wherein the specific power rate on the evaporation surface is adjusted by means of a scanning electron beam controlled by a scanning coil, that directs the electron beam across the surface of the starting material (compacted blank) according to a given program that is effected by means of an electromagnetic control device, the power of the scanning beam is 500 W-2 kW and the scanning frequency of the electron scanning beam being in the range from approximately 0.3 Hz to 300 Hz.

7. A method for producing thin film materials as in claim 1, wherein the power of the electron beam is automatically controlled by changing pressure in the gun and the electron beam diameter is from 5 mm to 10 mm.

8. A method for producing thin film materials as in claim 1, wherein the temperature of the substrate onto which the physical deposition of the vapor stream of the materials is being carried out is maintained within a given range by means of a radiation heater as a function of the reactive gas pressure in the deposition zone and of the partial pressure of the reactive gas in the working chamber and the localization of the substrate heating is effected by using screens and substrate holders.

9. A method for producing thin film materials as in claim 1, wherein the compacted blanks of the starting materials are placed inside of a cooled ceramic crucible or of a cooled metallic crucible.

10. A method for producing thin film materials as in claim 1, wherein the substrates onto which the physical deposition of the vapor stream of materials is being carried out are made of ceramics or of metal and the thickness of the metal from which the substrate is made is from 2 μm to 200 μm.

11. A method for producing thin film materials as in claim 1, wherein the substrate onto which the vapor stream of materials is being deposited is held at an adjustable electrical potential relative to the properties of the materials which are deposited.

12. A method for producing thin film materials as in claim 1, wherein the coating deposition rate equals more than 10 μm/s and is a function of the material that is evaporated.

13. A method for producing thin film materials as in claim 1, wherein prior to evaporation of the material being vaporized, the substrate surface is subjected to ion cleaning.

14. A method for producing thin film materials as in claim 1, wherein the initial materials may be comprised of metal oxides, metal sulphides, metals, carbon, cabon compositions, silicon or silicon composition and the materials being deposited onto the substrate may be comprised of active electrode materials of power sources such as MoO₃, FeS₂, LiCoO₂, LiMn₂O₄, MnO₂, carbon and carbon compositions, solid inorganic electrolytes, including those of the Lipon® type, or vitreous substances based on a lithium-containing mixture of oxides, materials for solar cell such as silicon or silicon composition.

15. A method for producing thin film materials as in claim 1, wherein a multi-layer coating is applied onto the substrate, the first layer of multi-layer coating being a layer of an adhesive material or graphite.
